(19) United States
(12) Patent Application Publication
(10) Pub. No.: US 2007/0280307 A1
(43) Pub. Date: Dec. 6, 2007

(54) SEMICONDUCTOR LASER DEVICE

(75) Inventors: Yasuhiro Kunitsugu, Tokyo (JP); Hiromasu Matsuoka, Itami-shi (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 11/755,818

(22) Filed: May 31, 2007

(30) Foreign Application Priority Data
Jun. 6, 2006 (JP) 2006-157280
Dec. 7, 2006 (JP) 2006-330589

(51) Int. Cl. H01S 3/10; H01S 5/00; H01S 3/04

(52) U.S. Cl. 372/23; 372/43.01; 372/49.01

(57) ABSTRACT

A semiconductor laser device for emitting light at two wavelengths λ₁ and λ₂ comprises: a laser chip having a front end face and a rear end face; and a high reflectance film on the rear end face of the laser chip and including seven or more layers laminated one on top of another, the seven or more layers including a first layer and a last layer, the first layer being closest to the laser chip, the last layer being farthest from the laser chip. One or more of the seven or more layers of the high reflectance film, other than the first and last layers, has an optical thickness of n*λ/2, where n is a natural number and λ=(λ₁+λ₂)/2. All of the seven or more layers of the high reflectance film, other than the one or more layers and other than the last layer, have an optical thickness of (2n′+1)*λ/4, where n′ is 0 or a positive integer. The last layer of the high reflectance film has an optical thickness of n*λ/4.

### FIELD OF THE INVENTION

The present invention relates to a semiconductor laser device that emits light at two wavelengths λ₁ and λ₂, and more particularly to a semiconductor laser device in which the reflectance of the high reflectance film formed on the rear end face of the laser chip is high at two wavelengths λ₁ and λ₂ and has only a small wavelength dependence.

### BACKGROUND ART

In a semiconductor laser device, each end face of the resonator, which is generally produced by cleaving a wafer, has dielectric films formed thereon. These dielectric films constitute a reflectance control film and are usually formed by vapor deposition, sputtering, or CVD, etc. The reflectance of the reflectance control film can be adjusted to a desired value by selecting or adjusting the type, thickness, and number of these dielectric films. Especially, high power semiconductor laser devices must be designed such that the rear end face side has high reflectance to increase the proportion of the laser light emitted from the front end face side.

A single-wavelength semiconductor laser device generally employs a film having an optical thickness of λ/4 as a high reflectance film to maximize the reflectance at the oscillation wavelength λ. However, in the case of a conventional semiconductor laser device that emits light at two wavelengths (λ₁, λ₂) 50 nm or more apart, if the optical thickness of the high reflectance film is adjusted to allow for a high reflectance at one wavelength (λ₁), it is difficult for the film to provide a high reflectance at the other wavelength (λ₂).

A conventional semiconductor laser device will be described with reference to FIGS. 19 to 25. FIG. 19 is a perspective view of a two-wavelength semiconductor laser device in which semiconductor laser elements for DVD and CD-R media are monolithically formed. The laser chip includes: a semiconductor substrate 1 of, e.g., GaAs; active layers 2 and 3 of the semiconductor laser elements for DVD and CD-R media, respectively, formed in the semiconductor substrate 1; a top electrode 4 formed on the top surface of the semiconductor substrate 1; and a bottom electrode 5 formed on the rear surface of the semiconductor substrate 1. The active layer 2 emits a laser beam 6 having wavelength λ₁ and the active layer 3 emits a laser beam 7 having wavelength λ₂. More specifically, the laser beam 6 is emitted by the semiconductor laser element for DVD media, and its wavelength λ₁ is 660 nm. The laser beam 7, on the other hand, is emitted by the semiconductor laser element for CD-R media, and its wavelength λ₂ is 780 nm.

FIG. 20 is a vertical cross-sectional view of a conventional semiconductor laser device taken along its optical axis. Referring to the figure, a low reflectance film 8 is formed on the front end face of the laser chip, and a high reflectance film 100 is formed on the rear end face of the laser chip.

FIG. 21 is an enlarged cross-sectional view of a conventional high reflectance film (100). Generally, a high reflectance film is formed by alternately laminating high refractive index films and low refractive index films. In this example, the high refractive index films are tantalum oxide (Ta₂O₅) films having a refractive index of 2.031, and the low refractive index films are aluminum oxide (Al₂O₃) films having a refractive index of 1.641 (see, e.g., Japanese Laid-Open Patent Publication No. 2004-327581). Specifically, the high reflectance film 100 includes 13 oxide films or layers such as (in the order of increasing distance from the laser chip) an aluminum oxide film 101, a tantalum oxide film 102, an aluminum oxide film 103, a tantalum oxide film 104, an aluminum oxide film 105, a tantalum oxide film 106, an aluminum oxide film 107, a tantalum oxide film 108, an aluminum oxide film 109, a tantalum oxide film 110, an aluminum oxide film 111, a tantalum oxide film 112, and an aluminum oxide film 113.

FIG. 22 shows a reflectance spectrum of a high reflectance film having an optical thickness of λ₁/4. In this case, the reflectance of the high reflectance film is 80% at wavelength λ₁, but only 5% at wavelength λ₂, that is, this high reflectance film cannot provide a reflectance of 60% or more (a general requirement) at wavelength λ₂. FIG. 23 shows a reflectance spectrum of a high reflectance film having an optical thickness of λ₂/4. In this case, although the reflectance of the high reflectance film is 80% at wavelength λ₂, it is only 8% at wavelength λ₁.

In order to achieve high reflectance at both wavelengths λ₁ and λ₂, a technique is proposed which forms a dielectric film (or high reflectance film) to an optical thickness of an integer multiple of λ/4, where λ=(λ₁+λ₂)/2. (See, e.g., Japanese Laid-Open Patent Publication No. 2001-257413.) However, this dielectric film (or high reflectance film) includes silicon (Si) films having a very high refractive index (3 or more) as high refractive index films in order to achieve a reflectance of 80% or higher. Therefore, it has a large optical absorption coefficient, meaning that the rear end face of the laser chip may degrade due to heat generated as a result of absorption of light.

FIG. 24 shows a reflectance spectrum of a dielectric film (or high reflectance film) that employs tantalum oxide films as high refractive index films and includes a total of 13 layers or films. The reflectance of this dielectric film is 68% at wavelength λ₁ and 83% at wavelength λ₂. However, it has a strong wavelength dependence; it reduces to 58% at (λ₁−10 nm). That is, the film has only a small wavelength margin for achieving the required high reflectance (60% or higher).

A common method for increasing the reflectance of a dielectric film or high reflectance film is to increase the number of layers in the film. FIG. 25 shows a reflectance spectrum of a dielectric film (or high reflectance film) that has 17 layers. This dielectric film exhibits reflectances of 68% and 81% at wavelengths λ₁ and λ₂, respectively, but has only a small wavelength margin for achieving the required high reflectance since it includes an increased number of layers.

Semiconductor laser devices for emitting light at two wavelengths λ₁ and λ₂ must have a configuration in which the high reflectance film formed on the rear end face of the laser chip has high reflectance at both wavelengths λ₁ and λ₂. However, it has been difficult to form a high reflectance film exhibiting high reflectance over a wide wavelength range. Furthermore, the reflectance of conventional high reflectance films has a strong wavelength dependence. To solve these problems, the high reflectance film may include a high refractive index film(s) having a large optical absorption coefficient. In this case, however, the rear end face of the laser chip may degrade due to absorption of light.

### SUMMARY OF THE INVENTION

The present invention has been devised to solve the above problems. It is, therefore, a first object of the present invention to provide a semiconductor laser device in which the reflectance of the high reflectance film formed on the rear end face of the laser chip is high at both of two wavelengths λ₁ and λ₂ and has only a small wavelength dependence. A second object of the present invention is to provide a semiconductor laser device configured to prevent degradation of the rear end face of its laser chip due to absorption of light.

According to one aspect of the present invention, a semiconductor laser device for emitting light at two wavelengths λ1 and λ2 comprises: a laser chip having a front end face and a rear end face; and a high reflectance film formed on the rear end face of the laser chip and including seven or more layers laminated one on top of another, the seven or more layers including a first layer and a last layer, the first layer being closest to the laser chip, the last layer being farthest from the laser chip; wherein one or more of the seven or more layers of the high reflectance film other than the first and last layers have an optical thickness of n*λ/2, where n is a natural number and λ=(λ₁+λ₂)/2; wherein all of the seven or more layers of the high reflectance film other than the one or more layers and other than the last layer have an optical thickness of (2n+1)*λ/4, where n is 0 or a positive integer and λ=(λ₁+λ₂)/2; and wherein the last layer of the high reflectance film has an optical thickness of n*λ/4, where n is a natural number and λ=(λ1+λ2)/2.

Thus, the present invention can provide a semiconductor laser device in which the reflectance of the high reflectance film formed on the rear end face of the laser chip is high at both of two wavelengths λ₁ and λ₂ and has only a small wavelength dependence.

### BRIEF DESCRIPTION OF THE DRAWINGS

FIG. 1 is a vertical cross-sectional view of the semiconductor laser device of the present embodiment taken along its optical axis.

FIG. 2 is an enlarged cross-sectional view of the high reflectance film of the present embodiment.

FIG. 3 shows a reflectance spectrum of the high reflectance film of the present embodiment.

FIG. 4 is a vertical cross-sectional view of a semiconductor laser device according to a second embodiment of the present invention taken along its optical axis.

FIG. 5 is an enlarged cross-sectional view of a high reflectance film of the second embodiment.

FIG. 6 shows a reflectance spectrum of the high reflectance film of the present embodiment.

FIG. 7 is a vertical cross-sectional view of a semiconductor laser device according to a third embodiment of the present invention taken along its optical axis.

FIG. 8 is an enlarged cross-sectional view of a high reflectance film of the third embodiment.

FIG. 9 shows a reflectance spectrum of the high reflectance film of the present embodiment.

FIG. 10 is a vertical cross-sectional view of a semiconductor laser device according to a fourth embodiment of the present invention taken along its optical axis.

FIG. 11 is an enlarged cross-sectional view of a high reflectance film of the fourth embodiment.

FIG. 12 shows a reflectance spectrum of the high reflectance film of the present embodiment.

FIG. 13 is a vertical cross-sectional view of a semiconductor laser device according to a fifth embodiment of the present invention taken along its optical axis.

FIG. 14 is an enlarged cross-sectional view of a high reflectance film of the fifth embodiment.

FIG. 15 shows a reflectance spectrum of the high reflectance film of the present embodiment.

FIG. 16 is a vertical cross-sectional view of a semiconductor laser device according to a sixth embodiment of the present invention taken along its optical axis.

FIG. 17 is an enlarged cross-sectional view of a high reflectance film of the sixth embodiment.

FIG. 18 shows a reflectance spectrum of the high reflectance film of the present embodiment.

FIG. 19 is a perspective view of a two-wavelength semiconductor laser device in which semiconductor laser elements for DVD and CD-R media are monolithically formed.

FIG. 20 is a vertical cross-sectional view of a conventional semiconductor laser device taken along its optical axis.

FIG. 21 is an enlarged cross-sectional view of a conventional high reflectance film.

FIG. 22 shows a reflectance spectrum of a high reflectance film having an optical thickness of λ₁/4.

FIG. 23 shows a reflectance spectrum of a high reflectance film having an optical thickness of λ₂/4.

FIG. 24 shows a reflectance spectrum of a dielectric film that employs tantalum oxide films as high refractive index films and includes a total of 13 layers or films.

FIG. 25 shows a reflectance spectrum of a dielectric film that has 17 layers.

### DETAILED DESCRIPTION OF THE PREFERRED EMBODIMENTS

### First Embodiment

A semiconductor laser device according to a first embodiment of the present invention will be described. This semiconductor laser device emits light at two wavelengths λ₁ and λ₂ 50 nm or more apart. Specifically, the semiconductor laser device includes two semiconductor laser elements for DVD and CD-R media, respectively, that emit light at wavelengths λ₁ and λ₂ respectively. In this case, the wavelength λ₁ is 660 nm and the wavelength λ₂ is 780 nm. That is, the average wavelength λ=(λ₁+λ₂)/2=720 nm.

FIG. 1 is a vertical cross-sectional view of the semiconductor laser device of the present embodiment taken along its optical axis. The laser chip includes: a semiconductor substrate 1 of, e.g., GaAs: active layers 2 and 3 of the semiconductor laser elements for DVD and CD-R media, respectively, formed in the semiconductor substrate 1; a top electrode 4 formed on the top surface of the semiconductor substrate 1; and a bottom electrode 5 formed on the rear surface of the semiconductor substrate 1. The active layer 2 emits a laser beam having wavelength λ₁ and the active layer 3 emits a laser beam having wavelength λ₂. Further, a low reflectance film 8 is formed on the front end face of the laser chip, and a high reflectance film 10 is formed on the rear end face of the laser chip.

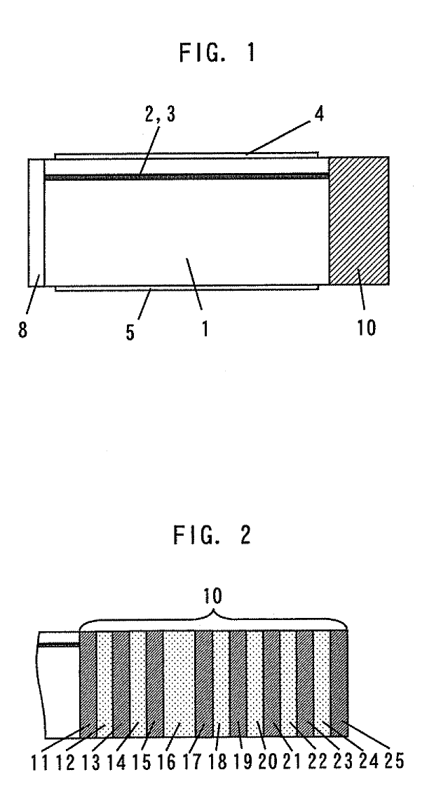

FIG. 2 is an enlarged cross-sectional view of the high reflectance film 10 of the present embodiment. The high reflectance film 10 includes tantalum oxide (Ta₂O₅) films having a refractive index of 2.031 as high refractive index films and aluminum oxide (Al₂O₃) films having a refractive index of 1.641 as low refractive index films. These high refractive index films and low refractive index films are alternately laminated one on top of another. Specifically, the high reflectance film 10 includes 15 oxide films or layers such as (in the order of increasing distance from the laser chip) a first-layer aluminum oxide film 11 having an optical thickness of λ/4, a second-layer tantalum oxide film 12 having an optical thickness of λ/4, a third-layer aluminum oxide film 13 having an optical thickness of λ/4, a fourth-layer tantalum oxide film 14 having an optical thickness of λ/4, a fifth-layer aluminum oxide film 15 having an optical thickness of λ/4, a sixth-layer tantalum oxide film 16 having an optical thickness of λ/2, a seventh-layer aluminum oxide film 17 having an optical thickness of λ/4, an eighth-layer tantalum oxide film 18 having an optical thickness of λ/4, a ninth-layer aluminum oxide film 19 having an optical thickness of λ/4, a tenth-layer tantalum oxide film 20 having an optical thickness of λ/4, an eleventh-layer aluminum oxide film 21 having an optical thickness of λ/4, a twelfth-layer tantalum oxide film 22 having an optical thickness of λ/4, a thirteenth-layer aluminum oxide film 23 having an optical thickness of λ/4, a fourteenth-layer tantalum oxide film 24 having an optical thickness of λ/4, and a fifteenth- or last-layer aluminum oxide film 25 having an optical thickness of λ/4.

Thus, the high reflectance film 10 is an example of a high reflectance film formed on the rear end face of a laser chip and having 7 or more layers that are laminated one on top of another wherein: one or more of the layers other than the first layer (which is closest to the laser chip) and the last layer (which is farthest from the laser chip) have an optical thickness of n*λ/2, where n is a natural number; all of the layers other than the one or more layers and other than the last layer have an optical thickness of (2n+1)*λ/4, where n is 0 or a positive integer; and the last layer has an optical thickness of n*λ/4, where n is a natural number. Note that λ=(λ₁+λ₂)/2. According to the present embodiment, the sixth-layer tantalum oxide film 16 having an optical thickness of λ/2 corresponds to the one or more layers having an optical thickness of n*λ/2.

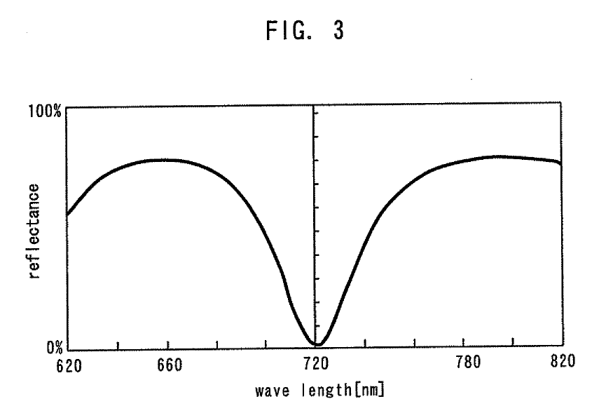

FIG. 3 shows a reflectance spectrum of the high reflectance film 10 of the present embodiment. The reflectance of this high reflectance film is 79% at wavelength λ₁ (660 nm) and 80% at wavelength λ₂ (780 nm). Thus, in the semiconductor laser device of the present embodiment, the reflectance of the high reflectance film 10 formed on the rear end face of the laser chip is high at both of the wavelengths λ₁ and λ₂ and has only a small wavelength dependence. Further, the first layer of the high reflectance film 10 in contact with the rear end face of the laser chip is made up of an aluminum oxide film, which has low optical absorption, preventing degradation of the rear end face of the laser chip due to absorption of light.

### Second Embodiment

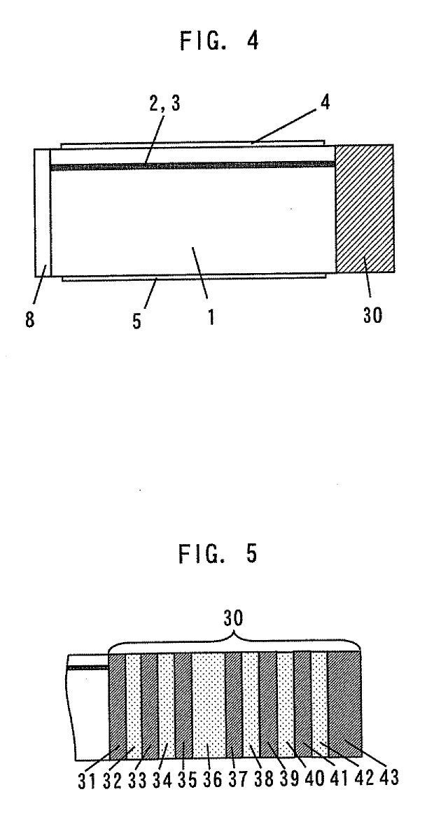

FIG. 4 is a vertical cross-sectional view of a semiconductor laser device according to a second embodiment of the present invention taken along its optical axis, and FIG. 5 is an enlarged cross-sectional view of a high reflectance film of the second embodiment. It should be noted that this semiconductor laser device is similar to that of the first embodiment except that the rear end face of the laser chip has a high reflectance film 30 formed thereon instead of the high reflectance film 10.

The high reflectance film 30 includes tantalum oxide (Ta₂O₅) films having a refractive index of 2.031 as high refractive index films and aluminum oxide (Al₂O₃) films having a refractive index of 1.641 as low refractive index films. These high refractive index films and low refractive index films are alternately laminated one on top of another. Specifically, the high reflectance film 30 includes 13 oxide films or layers such as (in the order of increasing distance from the laser chip) a first-layer aluminum oxide film 31 having an optical thickness of λ/4, a second-layer tantalum oxide film 32 having an optical thickness of λ/4, a third-layer aluminum oxide film 33 having an optical thickness of λ/4, a fourth-layer tantalum oxide film 34 having an optical thickness of λ/4, a fifth-layer aluminum oxide film 35 having an optical thickness of λ/4, a sixth-layer tantalum oxide film 36 having an optical thickness of λ/2, a seventh-layer aluminum oxide film 37 having an optical thickness of λ/4, an eighth-layer tantalum oxide film 38 having an optical thickness of λ/4, a ninth-layer aluminum oxide film 39 having an optical thickness of λ/4, a tenth-layer tantalum oxide film 40 having an optical thickness of λ/4, an eleventh-layer aluminum oxide film 41 having an optical thickness of λ/4, a twelfth-layer tantalum oxide film 42 having an optical thickness of λ/4, and a thirteenth- or last-layer aluminum oxide film 43 having an optical thickness of λ/2.

Thus, the high reflectance film 30 is an example of a high reflectance film formed on the rear end face of a laser chip and having 7 or more layers that are laminated one on top of another wherein: one or more of the layers other than the first layer (which is closest to the laser chip) and the last layer (which is farthest from the laser chip) have an optical thickness of n*λ/2, where n is a natural number; all of the layers other than the one or more layers and other than the last layer have an optical thickness of (2n+1)*λ/4, where n is 0 or a positive integer; and the last layer has an optical thickness of n*λ/4, where n is a natural number. Note that λ=(λ₁+λ₂)/2. According to the present embodiment, the sixth-layer tantalum oxide film 36 having an optical thickness of λ/2 corresponds to the one or more layers having an optical thickness of n*λ/2, and the thirteenth- or last-layer tantalum oxide film 42 having an optical thickness of λ/2 corresponds to the last layer having an optical thickness of n*λ/4.

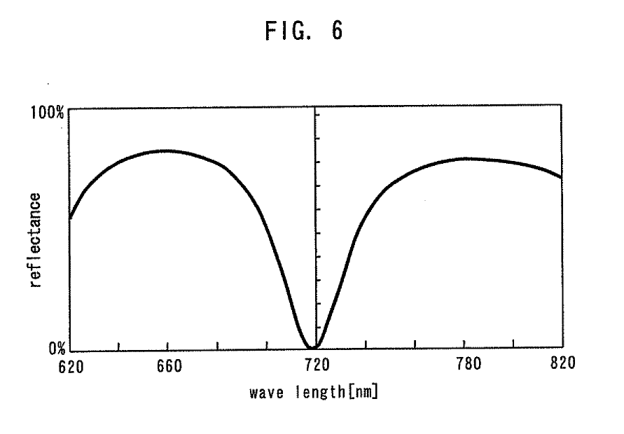

FIG. 6 shows a reflectance spectrum of the high reflectance film 30 of the present embodiment. The reflectance of this high reflectance film is 85% at wavelength λ₁ (660 nm) and 80% at wavelength λ₂ (780 nm). Thus, in the semiconductor laser device of the present embodiment, the reflectance of the high reflectance film 30 formed on the rear end face of the laser chip is high at both of the wavelengths λ₁ and λ₂ and has only a small wavelength dependence. Further, the first layer of the high reflectance film 30 in contact with the rear end face of the laser chip is made up of an aluminum oxide film, which has low optical absorption, preventing degradation of the rear end face of the laser chip due to absorption of light.

### Third Embodiment

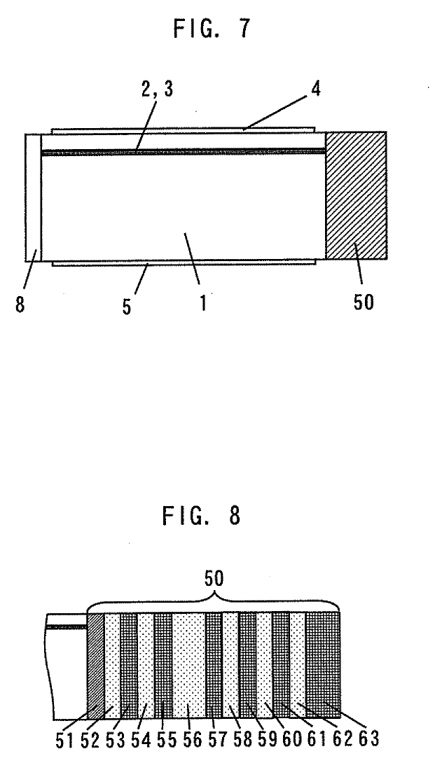

FIG. 7 is a vertical cross-sectional view of a semiconductor laser device according to a third embodiment of the present invention taken along its optical axis, and FIG. 8 is an enlarged cross-sectional view of a high reflectance film of the third embodiment. It should be noted that this semiconductor laser device is similar to that of the first embodiment except that the rear end face of the laser chip has a high reflectance film 50 formed thereon instead of the high reflectance film 10.

The high reflectance film 50 includes tantalum oxide (Ta₂O₅) films having a refractive index of 2.031 as high refractive index films and also includes an aluminum oxide (Al₂O₃) film having a refractive index of 1.641 and silicon oxide (SiO₂) films having a refractive index of 1.461 as low refractive index films. These high refractive index films and low refractive index films are alternately laminated one on top of another. Specifically, the high reflectance film 50 includes 13 oxide films or layers such as (in the order of increasing distance from the laser chip) a first-layer aluminum oxide film 51 having an optical thickness of λ/4, a second-layer tantalum oxide film 52 having an optical thickness of λ/4, a third-layer silicon oxide film 53 having an optical thickness of λ/4, a fourth-layer tantalum oxide film 54 having an optical thickness of λ/4, a fifth-layer silicon oxide film 55 having an optical thickness of λ/4, a sixth-layer tantalum oxide film 56 having an optical thickness of λ/2, a seventh-layer silicon oxide film 57 having an optical thickness of λ/4, an eighth-layer tantalum oxide film 58 having an optical thickness of λ/4, a ninth-layer silicon oxide film 59 having an optical thickness of λ/4, a tenth-layer tantalum oxide film 60 having an optical thickness of λ/4, an eleventh-layer silicon oxide film 61 having an optical thickness of λ/4, a twelfth-layer tantalum oxide film 62 having an optical thickness of λ/4, and a thirteenth- or last-layer silicon oxide film 63 having an optical thickness of λ/4.

Thus, the high reflectance film 50 is an example of a high reflectance film formed on the rear end face of a laser chip and having 7 or more layers that are laminated one on top of another wherein: one or more of the layers other than the first layer (which is closest to the laser chip) and the last layer (which is farthest from the chip) have an optical thickness of n*λ/2, where n is a natural number; all of the layers other than the one or more layers and other than the last layer have an optical thickness of (2n+1)*λ/4, where n is 0 or a positive integer; and the last layer has an optical thickness of n*λ/4, where n is a natural number. Note that λ=(λ₁+λ₂)/2. According to the present embodiment, the sixth-layer tantalum oxide film 56 having an optical thickness of λ/2 corresponds to the one or more layers having an optical thickness of n*λ/2.

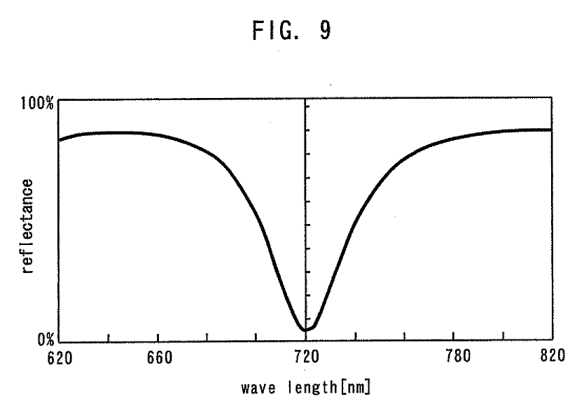

FIG. 9 shows a reflectance spectrum of the high reflectance film 50 of the present embodiment. The reflectance of this high reflectance film is 88% at wavelength λ₁ (660 nm) and 85% at wavelength λ₂ (780 nm). Thus, in the semiconductor laser device of the present embodiment, the reflectance of the high reflectance film 50 formed on the rear end face of the laser chip is high at both of the wavelengths λ₁ and λ₂ and has only a small wavelength dependence. Further, the first layer of the high reflectance film 50 in contact with the rear end face of the laser chip is made up of an aluminum oxide film, which has low optical absorption, preventing degradation of the rear end face of the laser chip due to absorption of light.

### Fourth Embodiment

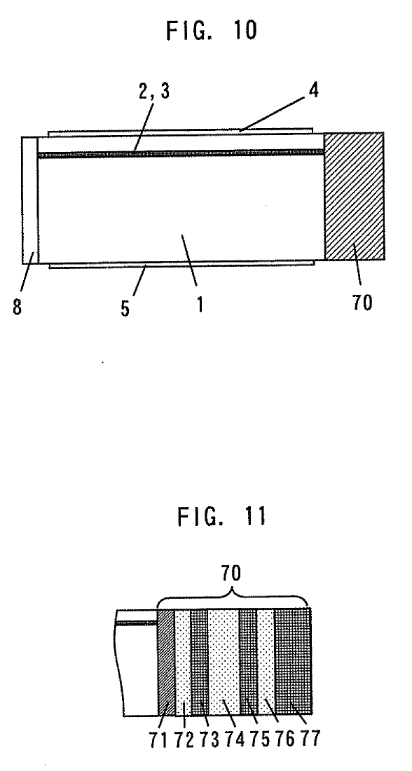

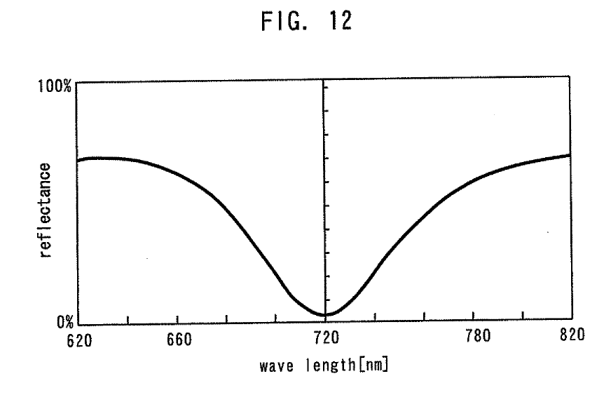

FIG. 10 is a vertical cross-sectional view of a semiconductor laser device according to a fourth embodiment of the present invention taken along its optical axis, and FIG. 11 is an enlarged cross-sectional view of a high reflectance film of the fourth embodiment. It should be noted that this semiconductor laser device is similar to that of the first embodiment except that the rear end face of the laser chip has a high reflectance film 70 formed thereon instead of the high reflectance film 10.

The high reflectance film 70 includes tantalum oxide (Ta₂O₅) films having a refractive index of 2.031 as high refractive index films and also includes an aluminum oxide (Al₂O₃) film having a refractive index of 1.641 and silicon oxide (SiO₂) films having a refractive index of 1.461 as low refractive index films. These high refractive index films and low refractive index films are alternately laminated one on top of another. Specifically, the high reflectance film 70 includes 7 oxide films or layers such as (in the order of increasing distance from the laser chip) a first-layer aluminum oxide film 71 having an optical thickness of λ/4, a second-layer tantalum oxide film 72 having an optical thickness of λ/4, a third-layer silicon oxide film 73 having an optical thickness of λ/4, a fourth-layer tantalum oxide film 74 having an optical thickness of λ/2, a fifth-layer silicon oxide film 75 having an optical thickness of λ/4, a sixth-layer tantalum oxide film 76 having an optical thickness of λ/4, and a seventh- or last-layer silicon oxide film 77 having an optical thickness of λ/2.

Thus, the high reflectance film 70 is an example of a high reflectance film formed on the rear end face of a laser chip and having 7 or more layers that are laminated one on top of another wherein: one or more of the layers other than the first layer (which is closest to the laser chip) and the last layer (which is farthest from the laser chip) have an optical thickness of n*λ/2, where n is a natural number; all of the layers other than the one or more layers and other than the last layer have an optical thickness of (2n+1)*λ/4, where n is 0 or a positive integer; and the last layer has an optical thickness of n*λ/4, where n is a natural number. Note that λ=(λ₁+λ₂)/2. According to the present embodiment, the fourth-layer tantalum oxide film 74 having an optical thickness of λ/2 corresponds to the one or more layers having an optical thickness of n*λ/2, and the seventh- or last-layer tantalum oxide film 77 having an optical thickness of λ/2 corresponds to the last layer having an optical thickness of n*λ/4.

FIG. 12 shows a reflectance spectrum of the high reflectance film 70 of the present embodiment. The reflectance of this high reflectance film is 63% at wavelength λ₁ (660 nm) and 60% at wavelength λ₂ (780 nm). Thus, in the semiconductor laser device of the present embodiment, the reflectance of the high reflectance film 70 formed on the rear end face of the laser chip is high at both of the wavelengths λ₁ and λ₂ and has only a small wavelength dependence. Further, the first layer of the high reflectance film 70 in contact with the rear end face of the laser chip is made up of an aluminum oxide film, which has low optical absorption, preventing degradation of the rear end face of the laser chip due to absorption of light.

### Fifth Embodiment

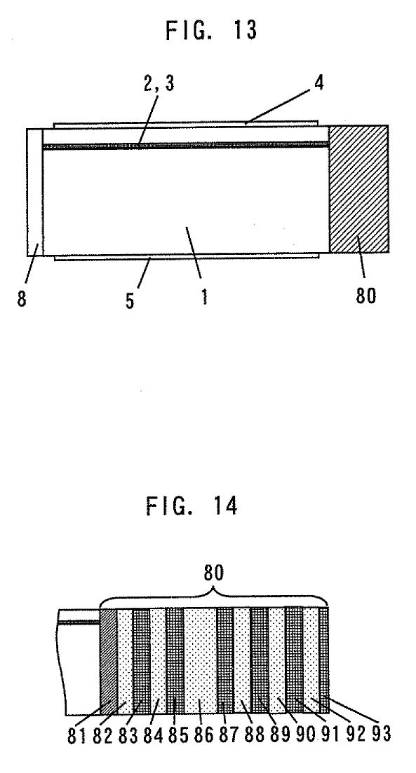

FIG. 13 is a vertical cross-sectional view of a semiconductor laser device according to a fifth embodiment of the present invention taken along its optical axis, and FIG. 14 is an enlarged cross-sectional view of a high reflectance film of the fifth embodiment. It should be noted that this semiconductor laser device is similar to that of the first embodiment except that the rear end face of the laser chip has a high reflectance film 80 formed thereon instead of the high reflectance film 10.

The high reflectance film 80 includes tantalum oxide (Ta₂O₅) films having a refractive index of 2.031 as high refractive index films and also includes an aluminum oxide (Al₂O₃) film having a refractive index of 1.641 and silicon oxide (SiO₂) films having a refractive index of 1.461 as low refractive index films. These high refractive index films and low refractive index films are alternately laminated one on top of another. Specifically, the high reflectance film 80 includes 13 oxide films or layers such as (in the order of increasing distance from the laser chip) a first-layer aluminum oxide film 81 having an optical thickness of λ/4, a second-layer tantalum oxide film 82 having an optical thickness of λ/4, a third-layer silicon oxide film 83 having an optical thickness of λ/4, a fourth-layer tantalum oxide film 84 having an optical thickness of λ/4, a fifth-layer silicon oxide film 85 having an optical thickness of λ/4, a sixth-layer tantalum oxide film 86 having an optical thickness of λ/4, a seventh-layer silicon oxide film 87 having an optical thickness of λ/4, an eighth-layer tantalum oxide film 88 having an optical thickness of λ/2, a ninth-layer silicon oxide film 89 having an optical thickness of λ/4, a tenth-layer tantalum oxide film 90 having an optical thickness of λ/4, an eleventh-layer silicon oxide film 91 having an optical thickness of λ/4, a twelfth-layer tantalum oxide film 92 having an optical thickness of λ/4, and a thirteenth- or last-layer silicon oxide film 93 having a thickness of 150 Å.

Thus, the high reflectance film 80 is an example of a high reflectance film formed on the rear end face of a laser chip and having 7 or more layers that are laminated one on top of another wherein: one of the layers other than the first layer (which is closest to the laser chip) and the last layer (which is farthest from the laser chip) has an optical thickness of n*λ/2, where n is a natural number; all of the layers other than the one layer and other than the last layer have an optical thickness of (2n+1)*λ/4, where n is 0 or a positive integer; and the last layer is a protective film having a thickness of 10 Å-150 Å. Note that λ=(λ₁+λ₂)/2. According to the present embodiment, the eighth-layer tantalum oxide film 88 having an optical thickness of λ/2 corresponds to the one layer having an optical thickness of n*λ/2.

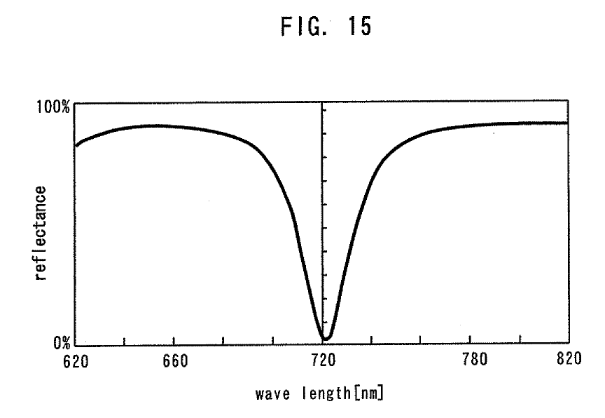

FIG. 15 shows a reflectance spectrum of the high reflectance film 80 of the present embodiment. The reflectance of this high reflectance film is 92% at wavelength λ₁ (660 nm) and at wavelength λ₂ (780 nm). Thus, in the semiconductor laser device of the present embodiment, the reflectance of the high reflectance film 80 formed on the rear end face of the laser chip is high at both of the wavelengths λ₁ and λ₂ and has only a small wavelength dependence. Further, the first layer of the high reflectance film 80 in contact with the rear end face of the laser chip is made up of an aluminum oxide film, which has low optical absorption, preventing degradation of the rear end face of the laser chip due to absorption of light.

### Sixth Embodiment

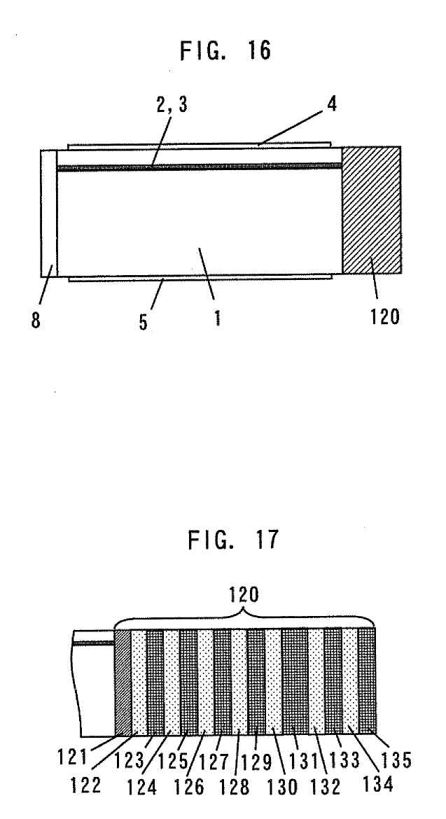

FIG. 16 is a vertical cross-sectional view of a semiconductor laser device according to a sixth embodiment of the present invention taken along its optical axis, and FIG. 17 is an enlarged cross-sectional view of a high reflectance film of the sixth embodiment. It should be noted that the this semiconductor laser device is similar to that of the first embodiment except that the rear end face of the laser chip has a high reflectance film 120 formed thereon instead of the high reflectance film 10.

The high reflectance film 120 includes tantalum oxide (Ta₂O₅) films having a refractive index of 2.031 as high refractive index films and also includes an aluminum oxide (Al₂O₃) film having a refractive index of 1.641 and silicon oxide (SiO₂) films having a refractive index of 1.461 as low refractive index films. These high refractive index films and low refractive index films are alternately laminated one on top of another. Specifically, the high reflectance film 120 includes 15 oxide films or layers such as (in the order of increasing distance from the laser chip) a first-layer aluminum oxide film 121 having an optical thickness of λ/4, a second-layer tantalum oxide film 122 having an optical thickness of λ/4, a third-layer silicon oxide film 123 having an optical thickness of λ/4, a fourth-layer tantalum oxide film 124 having an optical thickness of λ/4, a fifth-layer silicon oxide film 125 having an optical thickness of λ/4, a sixth-layer tantalum oxide film 126 having an optical thickness of λ/4, a seventh-layer silicon oxide film 127 having an optical thickness of λ/4, an eighth-layer tantalum oxide film 128 having an optical thickness of λ/4, a ninth-layer silicon oxide film 129 having an optical thickness of λ/4, a tenth-layer tantalum oxide film 130 having an optical thickness of λ/4, an eleventh-layer silicon oxide film 131 having an optical thickness of λ/2, a twelfth-layer tantalum oxide film 132 having an optical thickness of λ/4, a thirteenth-layer silicon oxide film 133 having an optical thickness of λ/4, a fourteenth-layer tantalum oxide film 134 having an optical thickness of λ/4, and a fifteenth- or last-layer silicon oxide film 135 having a thickness of 150 Å.

Thus, the high reflectance film 120 is an example of a high reflectance film formed on the rear end face of a laser chip and including seven or more layers that are laminated one on top of another wherein: one of the layers other than the first layer (which is closest to the laser chip) and the last layer (which is farthest from the laser chip) has an optical thickness of n*λ/2, where n is a natural number; all of the layers other than the one layer and other than the last layer have an optical thickness of (2n+1)*λ/4, where n is 0 or a positive integer; and the last layer is a protective film having a thickness of 10 Å-150 Å. Note that λ=(λ₁+λ₂)/2. According to the present embodiment, the eleventh-layer silicon oxide film 131 having an optical thickness of λ/2 corresponds to the one layer having an optical thickness of n*λ/2.

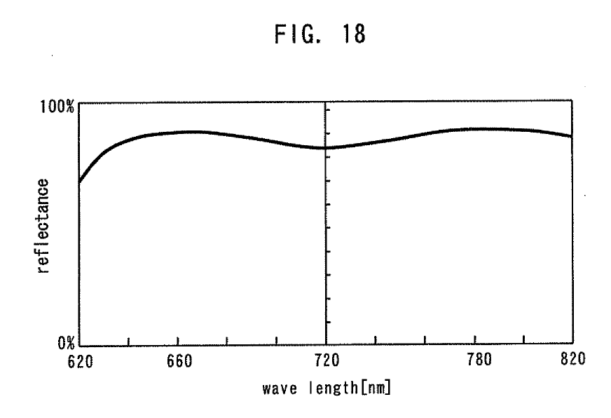

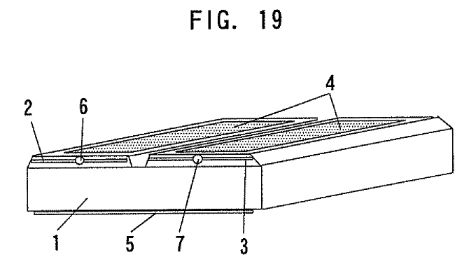

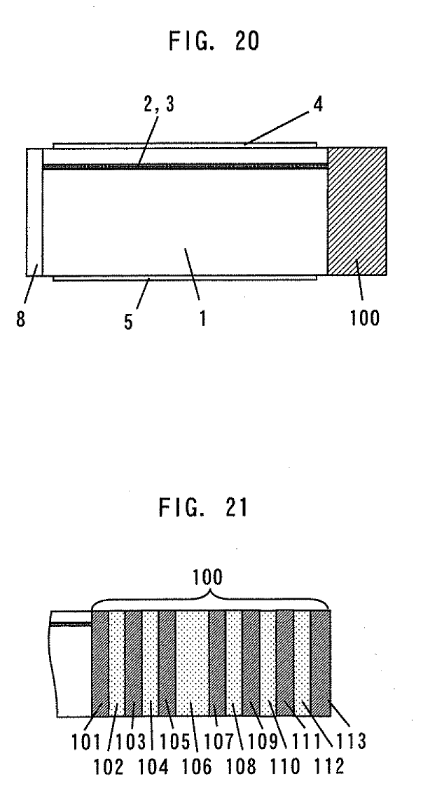

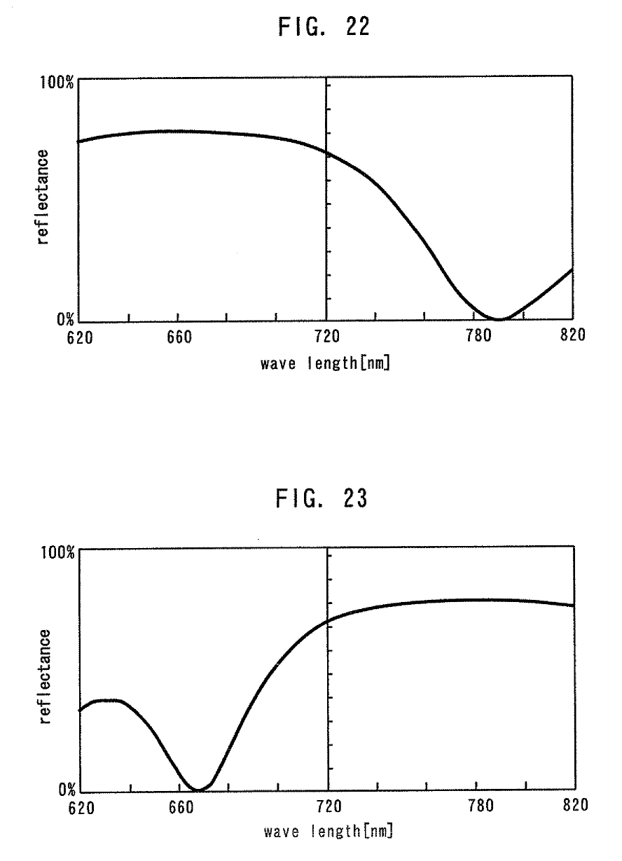

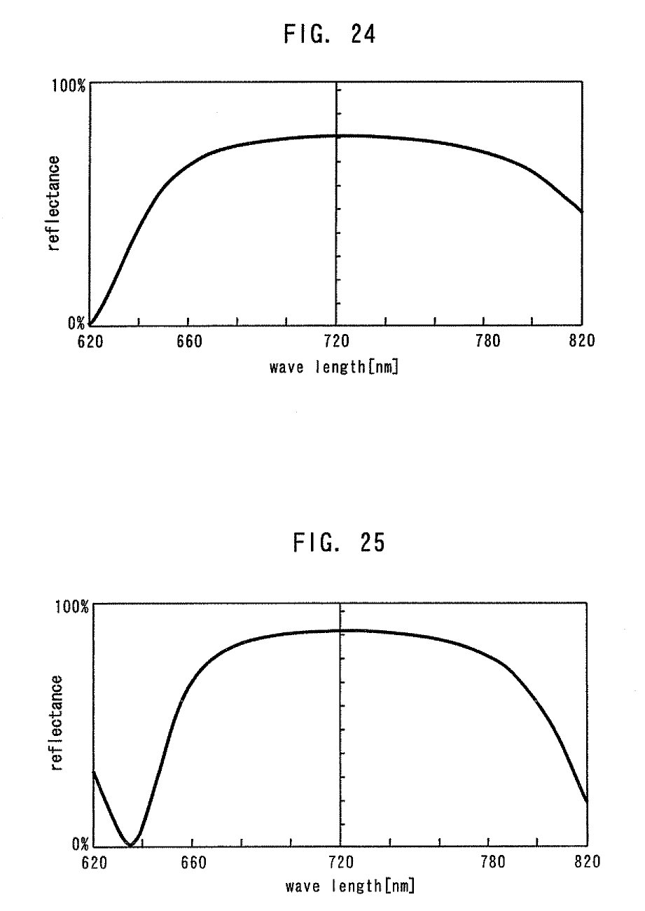

FIG. 18 shows a reflectance spectrum of the high reflectance film 120 of the present embodiment. The reflectance of this high reflectance film is 92% at wavelength λ₁ (660 nm) and at wavelength λ₂ (780 nm). Thus, in the semiconductor laser device of the present embodiment, the reflectance of the high reflectance film 120 formed on the rear end face of the laser chip is high at both of the wavelengths λ₁ and λ₂ and has only a small wavelength dependence. Further, the first layer of the high reflectance film 120 in contact with the rear end face of the laser chip is made up of an aluminum oxide film, which has low optical absorption, preventing degradation of the rear end face of the laser chip due to absorption of light.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2006-330589, filed on Dec. 7, 2006 including specification, claims, drawings and summary, on which the Convention priority of the present application is based, are incorporated herein by reference in its entirety.

1. A semiconductor laser device emitting light at two wavelengths, λ₁ and λ₂, comprising:
a laser chip having a front end face and a rear end face; and
a high reflectance film on said rear end face of said laser chip and including seven or more layers laminated one on top of another, said seven or more layers including a first layer and a last layer, said first layer being closest to said laser chip, said last layer being farthest from said laser chip, wherein
one or more of said seven or more layers of said high reflectance film, other than said first and last layers, has an optical thickness of n*λ/2, where n is a natural number and λ=(λ₁+λ₂)/2;
all of said seven or more layers of said high reflectance film, other than said one or more layers and other than said last layer, has an optical thickness of (2n+1)*λ/4, and
said last layer of said high reflectance film has an optical thickness of n*λ/4.

2. The semiconductor laser device as claimed in claim 1, wherein:
said first layer of said high reflectance film is aluminum oxide; and
one or more of said seven or more layers of said high reflectance film, other than said first layer is tantalum oxide.

3. The semiconductor laser device as claimed in claim 1, wherein:
said first layer of said high reflectance film is aluminum oxide; and
one or more of said seven or more layers of said high reflectance film, other than said first layer, is tantalum oxide or silicon oxide.

4. The semiconductor laser device as claimed in claim 1, wherein odd-numbered ones of said seven or more layers of said high reflectance film are aluminum oxide and even-numbered ones of said seven or more layers of said high reflectance film are tantalum oxide, said seven or more layers being counted in order of increasing distance from said laser chip.

5. The semiconductor laser device as claimed in claim 1, wherein:
said first layer of said high reflectance film is aluminum oxide; and
even-numbered ones of said seven or more layers of said high reflectance film are tantalum oxide and odd-numbered ones of said seven or more layers of said high reflectance film, other than said first layers ar silicon oxide, said seven or more layers being counted in order of increasing distance from said laser chip.

6. A semiconductor laser device emitting light at two wavelengths, λ₁ and λ₂, comprising:
a laser chip having a front end face and a rear end face; and
a high reflectance film on said rear end face of said laser chip and having seven or more layers laminated one on top of another, said seven or more layers including a first layer and a last layer, said first layer being closest to said laser chip, and said last layer being farthest from said laser chip, wherein
one of said seven or more layers of said high reflectance film, other than said first and last layers, has an optical thickness of n*λ/2, where n is a natural number and λ=(λ₁+λ₂)/2,
all of said seven or more layers of said high reflectance film, other than said one layer and other than said last layer have an optical thickness of (2n′+1)*λ/4, where n′ is 0 or a positive integer, and
said last layer of said high reflectance film is a protective film having a thickness in a range from 10 Å-to 150 Å.

7. The semiconductor laser device as claimed in claim 1, wherein the two wavelengths λ₁ and λ₂ are spaced at least 50 nm apart from each other.

8. The semiconductor laser device as claimed in claim 6, wherein the two wavelengths λ₁ and λ₂ are spaced at least 50 nm apart from each other.
